(19) United States
(12) Patent Application Publication
(10) Pub. No.: US 2004/0192051 A1
(43) Pub. Date: Sep. 30, 2004

(54) Method of forming a damascene structure

(75) Inventors: Hiroya Tanaka, Tomisato-shi (JP); Yoshio Ishikawa, Narita-shi (JP); Keiji Horioka, Mihama-ku (JP); Yuzuru Ueda, Narita-shi (JP); Hidetaka Oshio, Narita-shi (JP)

Correspondence Address: MOSER, PATTERSON & SHERIDAN, LLP, APPLIED MATERIALS INC, 595 SHREWSBURY AVE, SUITE 100, SHREWSBURY, NJ, 07702, US

(73) Assignee: Applied Materials, Inc.

(21) Appl. No.: 10/699,157

(22) Filed: Oct. 30, 2003

(30) Foreign Application Priority Data
Mar. 27, 2003 (JP) 2003-87893

(51) Int. Cl. H01L 21/311; H01L 21/302; H01L 21/461

(52) U.S. Cl. 438/697

(57) ABSTRACT

A method of forming a damascene structure including an insulator portion having a barrier layer comprising silicon carbide (SiC) or silicon carbon nitride (SiCN) on a metal wiring layer formed on a substrate. The method includes the steps of supplying a gas mixture comprising trifluoromethane (CHF₃) to a chamber accommodating the substrate and generating a plasma in the chamber, thereby forming a via hole communicating with the metal wiring layer through the first layer containing silicon carbide (SiC) or silicon carbon nitride (SiCN).

### CROSS-REFERENCE TO RELATED APPLICATIONS

This application claims benefit of Japanese Patent Application Serial No. 2003-87893, filed Mar. 27, 2003 (Attorney docket No. AMJ933-937), which is herein incorporated by reference in its entirety.

### BACKGROUND OF THE INVENTION

1. Field of the Invention

The present invention relates to a method of forming a damascene structure.

2. Description of the Related Art

As wiring structures have become finer in integrated circuits, attempts have been made to use a damascene structure in such wiring structure. Generally, an insulator portion in which a damascene structure is formed comprises a barrier layer integrated on the metal wiring layer, and an insulator layer integrated on the barrier layer. In a damascene structure, via holes are formed by RIE (Reactive Ion Etching) in the barrier layer, an insulator layer is laminated on the metal wiring layer, and trenches are formed in the insulator layer by RIE. The via holes and trenches are plated with a wiring material, and the surface of the insulator layer is polished by CMP (Chemical Mechanical Polishing), thereby forming a damascene structure. The barrier layer is generally formed of silicon nitride (Si₃N₄), and the like. For etching of the barrier layer, a process gas mainly comprising difluoromethane (CH₂F₂), and the like is used in order to obtain selectivity to the silicon nitride (Si₃N₄), as disclosed, for example, in Japanese Patent Application No. 2000-091425.

As wiring structures have become smaller, the dielectric constant of the insulating layer and the barrier layer have also been lowered, and a low dielectric constant material, such as silicon carbide (SiC), silicon carbon nitride (SiCN), and the like may be used. However, when a barrier layer containing silicon carbide (SiC) or silicon carbon nitride (SiCN) is etched using conventional process gases mainly comprising difluoromethane (CH₂F₂), polymers containing carbon atoms and hydrogen atoms may be deposited in the process chamber, thereby lowering the Mean Wafers Between Cleaning (MWBC) for such process chambers.

It is hence an object of the present invention to provide a method of forming a damascene structure in an insulator portion having a barrier layer comprising silicon carbide (SiC) or silicon carbon nitride (SiCN), while maintaining a favorable MWBC (Mean Wafers Between Cleaning) for a process chamber.

### SUMMARY OF THE INVENTION

The present invention is a method of forming a damascene structure including an insulator portion having a barrier layer comprising silicon carbide (SiC) or silicon carbon nitride (SiCN) on a metal wiring layer formed on a substrate. The method includes the steps of supplying a gas mixture comprising trifluoromethane (CHF₃) to a chamber accommodating the substrate and generating a plasma in the chamber, thereby forming a via hole communicating with the metal wiring layer through the barrier layer comprising silicon carbide (SiC) or silicon carbon nitride (SiCN).

### BRIEF DESCRIPTION OF THE DRAWINGS

The teachings of the present invention can be readily understood by considering the following detailed description in conjunction with the accompanying drawings, in which:

FIG. 1 is a schematic view of a substrate processing system suitable for performing portions of the present invention;

FIG. 2 is a schematic view of a processing chamber of the substrate processing system depicted in FIG. 1;

FIG. 3(a) is a cross-sectional view of a substrate showing a first resist mask for forming a via hole on an insulator portion;

FIG. 3(b) is a cross-sectional view of the substrate of FIG. 3(a) showing a via hole formed through the insulator portion;

FIG. 3(c) is a cross-sectional view of the substrate of FIG. 3(b) having the first resist mask removed therefrom;

FIG. 3(d) is a cross-sectional view of the substrate of FIG. 3(c) having a mask for forming a trench on the insulator portion;

FIG. 3(e) is a cross-sectional view of the substrate of FIG. 3(d) having the trench formed in the insulator portion;

FIG. 3(f) is a cross-sectional view of the substrate of FIG. 3(e) showing a step of removing the trench forming mask;

FIG. 3(g) is a cross-sectional view showing formation of the via hole in a barrier layer under the insulator portion;

FIG. 4(a) shows the state of a cleaned reaction chamber;

FIG. 4(b) shows the state of the reaction chamber shown in FIG. 4(a) after 2 hours of etching using trifluoromethane (CHF₃) as a process gas;

FIG. 4(c) shows the state of a cleaned reaction chamber;

FIG. 4(d) shows the state of the reaction chamber shown in FIG. 4(c) after 2 hours of etching using difluoromethane (CH₂F₂) as a process gas;

FIG. 5(a) is a cross-sectional view of a substrate showing a first resist mask for forming a via hole on an insulator portion according to a second embodiment;

FIG. 5(b) is a cross-sectional view of the substrate of FIG. 5(a) showing a via hole formed through the insulator portion;

FIG. 5(c) is a cross-sectional view of the substrate of FIG. 5(b) having the first resist mask removed therefrom;

FIG. 5(d) is a cross-sectional view of the substrate of FIG. 5(c) having a mask for forming a trench on the insulator portion;

FIG. 5(e) is a cross-sectional view of the substrate of FIG. 5(d) having the trench formed in the insulator portion;

FIG. 5(f) is a cross-sectional view of the substrate of FIG. 5(e) showing a step of removing the trench forming mask;

FIG. 5(g) is a cross-sectional view showing formation of the via hole in a barrier layer under the insulator portion;

FIG. 6 is a graph showing resistance measurement results for multi-layer wiring manufactured by the method described with reference to FIGS. 5(a)-5(g);

FIG. 7(a) is a cross-sectional view of the substrate manufactured by the method described with reference to FIGS. 5(a)-5(g);

FIG. 7(b) is an SEM photograph showing a section of a first insulator layer in the bottom of a trench manufactured by the method described with reference to FIGS. 5(a)-5(g);

FIG. 7(c) is an SEM photograph showing a section of a first insulator layer in the bottom of a trench manufactured using a prior art method;

FIG. 8(a) is a cross-sectional view of a substrate showing a first resist mask for forming a via hole on an insulator portion;

FIG. 8(b) is a cross-sectional view of the substrate of FIG. 8(a) showing a via hole formed through the insulator portion;

FIG. 8(c) is a cross-sectional view of the substrate of FIG. 8(b) having the first resist mask removed therefrom;

FIG. 8(d) is a cross-sectional view of the substrate of FIG. 8(c) having a mask for forming a trench on the insulator portion;

FIG. 8(e) is a cross-sectional view of the substrate of FIG. 8(d) having the trench formed in the insulator portion;

FIG. 8(f) is a cross-sectional view of the substrate of FIG. 8(e) showing a step of removing the trench forming mask;

FIG. 8(g) is a cross-sectional view showing formation of the via hole in a barrier layer under the insulator portion;

FIG. 9(a) is a cross-sectional view of the substrate manufactured by the method described with reference to FIGS. 8(a)-8(g);

FIG. 9(b) is an SEM photograph showing a section of a first insulator layer in the bottom of a trench manufactured by providing a process gas mixture of CHF₃:N₂ at a flow ratio of 30:50;

FIG. 9(c) is an SEM photograph showing a section of a first insulator layer in the bottom of a trench manufactured by providing a process gas mixture of CHF₃:O₂:N₂ at a flow ratio of 30:5:50;

FIG. 9(d) is an SEM photograph showing a section of a first insulator layer in the bottom of a trench manufactured by providing a process gas mixture of CHF₃:O₂at a flow ratio of 30:10;

FIG. 9(e) is a SEM photograph showing a section of a first insulator layer in the bottom of a trench manufactured by providing a process gas mixture of CHF₃:O₂:N₂ at a flow ratio of 30:10:50; and

FIG. 9(f) is a SEM photograph showing a section of a first insulator layer in the bottom of a trench manufactured by providing a process gas mixture of CHF₃:O₂: Ar at a flow ratio of 30:10:50.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

According to the present invention, the process gas used for etching a barrier layer formed of silicon carbide (SiC) or silicon carbon nitride (SiCN) of an insulator portion of a damascene structure includes trifluoromethane (CHF₃). The trifluoromethane (CHF₃) has a hydrogen atom content that is lowered as compared with the conventional process gas such as difluoromethane (CH₂F₂). Therefore, when etching with trifluoromethane (CHF₃) there is hardly any deposition of polymers in the chamber by reaction between carbon atoms and hydrogen atoms so the Mean Wafers Between Cleaning (MWBC) for the process chamber can be improved.

In the method of forming a damascene structure of the present invention, the insulator portion also has a dielectric layer formed of an oxide (e.g., silicon dioxide (SiO₂)) which is disposed on the barrier layer of silicon carbide (SiC) or silicon carbon nitride (SiCN). A via hole is formed in the dielectric layer that is concentric with a via hole formed in the barrier layer.

According to the present invention, by using the process gas including trifluoromethane (CHF₃), the barrier layer of silicon carbide (SiC) or silicon carbon nitride (SiCN) can be etched selectively.

Also to achieve the above object, the method of the present invention is a method of forming a damascene structure in an insulator portion having a barrier layer formed of a silicon carbide-containing material such as, for example, silicon carbide (SiC), silicon carbon nitride (SiCN), and the like, that is formed on a metal wiring layer provided on a substrate, comprising the steps of supplying a first gas containing oxygen into a chamber and generating plasma in the chamber to remove a first resist mask formed on a dielectric layer after a via hole has been defined therein, and supplying a second gas comprising trifluoromethane (CHF₃) into the chamber and generating a plasma in the chamber to form a via hole communicating with the metal wiring layer through the barrier layer of silicon carbide (SiC) or silicon carbon nitride (SiCN).

According to the present invention, the process gas used in etching of the barrier layer of silicon carbide (SiC) or silicon carbon nitride (SiCN) includes trifluoromethane (CHF₃) which has a hydrogen atom content that is lowered as compared with the conventional process gas containing difluoromethane (CH₂F₂). Therefore, since there is hardly any deposition of polymers in the chamber by reaction between carbon atoms and hydrogen atoms, the MWBC can be improved. Further, since the ashing process by oxygen plasma to remove the first resist is executed in the chamber, if the polymers are deposited in the chamber, the polymers are removed by oxygen plasma ashing.

The method of forming a damascene structure of the present invention further comprises the steps of forming a second resist mask on the dielectric layer for forming a trench and forming a trench in the dielectric layer by etching such dielectric layer.

In this method, after a via hole is formed in the dielectric layer, a trench is further formed in the dielectric layer. Since the process gas containing trifluoromethane (CHF₃) is used in etching the barrier layer, there is hardly any deposition of polymers in the chamber. Therefore, since polymers are also hardly deposited on the metal wiring of the metal wiring layer, the resistance value of the multi-layer wiring can be kept small. Besides, as there is hardly any deposition of polymers on the inner wall of the trench in the insulator layer, the problem of roughening of the trench inner wall due to the process gas by the polymers acting as micro mask is avoided.

It has been discovered that the trench inner wall is roughened when both oxygen (O₂) and nitrogen (N₂) are further added to the process gas comprising trifluoromethane (CHF₃) because the trench inner wall is exposed to the process gas for a long period, and that the trench inner wall is kept flat when oxygen (O₂) or nitrogen (N₂) is selectively included in the process gas. On the basis of this finding, in the method of forming a damascene structure of the present invention, the second gas includes at least one of oxygen (O₂) or nitrogen (N₂).

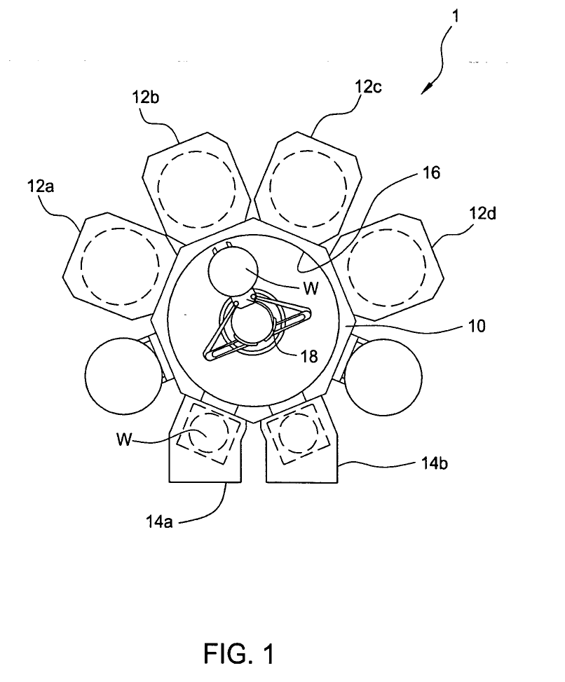

A method of forming a damascene structure according to a first embodiment of the present invention is explained below by referring to the accompanying drawings. In the following explanation of embodiments, same or corresponding parts in the drawings are identified with same reference numerals. FIG. 1 is a drawing schematically showing a substrate processing system 1 used in this method. An exemplary system is the CENTURA® processing system available from Applied Materials, Inc. of Santa Clara, Calif.

The substrate processing system 1 is a so-called single wafer multi-chamber type apparatus. In the substrate processing system 1, a plurality of processing chambers 12a, 12b, 12c, 12d and load lock chambers 14a, 14b are connected around a base block 10. In the substrate processing system 1, wafers W are conveyed among the load lock chambers 14a, 14b and processing chambers 12a to 12d by a conveying robot 18 provided in a conveying chamber 16 in the base block 10 to be processed.

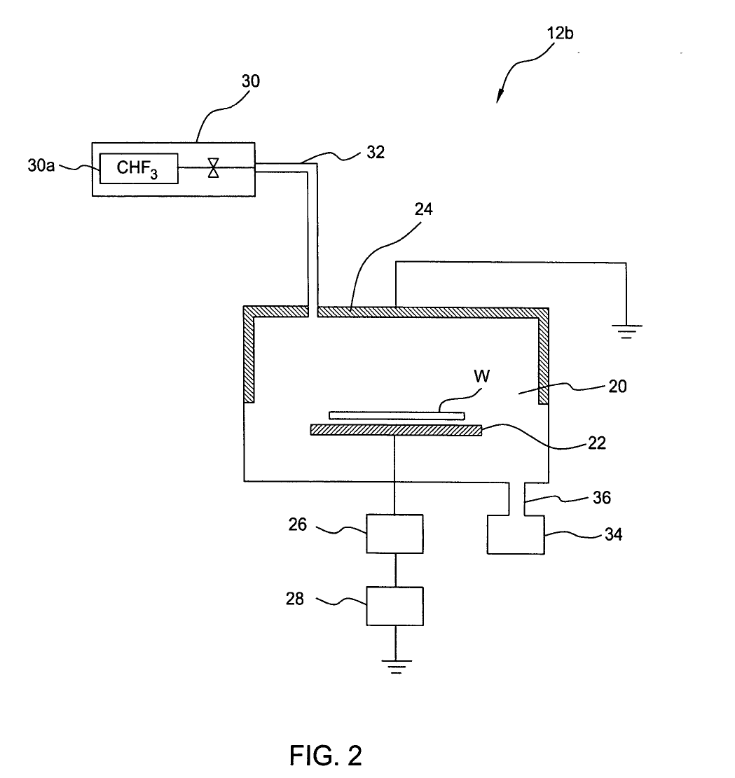

The processing chambers 12a to 12d have a similar structure. FIG. 2 is a view schematically showing the processing chamber 12b. The processing chamber 12b has a reaction chamber 20. The reaction chamber 20 has a pair of parallel flat electrodes 22 and 24, with the electrode 22 also functioning as a support unit for supporting the wafer W. An impedance matching device 26 is connected to the electrode 22, and a high frequency power supply unit 28 is connected to the impedance matching device 26. The high frequency power supply unit 28 can generate a high frequency electric power having a frequency within a specified range. A high frequency electric power is supplied to the electrode 22 through the impedance matching device 26, so that a plasma can be generated between the parallel flat electrodes 22 and 24 in the processing chamber 12a.

The processing chamber 12b includes a gas supply system 30, such that a process gas from the gas supply process is provided to the reaction chamber 20 by way of a conduit 32. The gas supply system 30 according to the embodiment shown has a gas supply source 30a for supplying the etchant gases (e.g., trifluoromethane (CHF₃) and the like). The processing chamber 12a also includes a vacuum pump 34 for evacuating the reaction chamber 20. The vacuum pump 34 is connected to the reaction chamber 20 through an exhaust pipe 36.

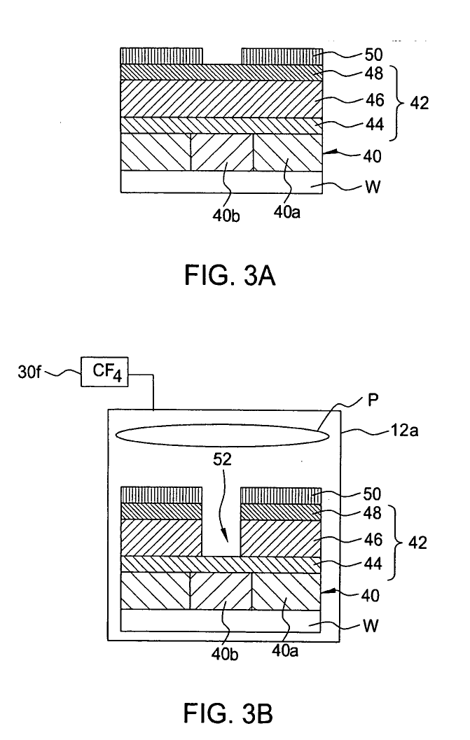

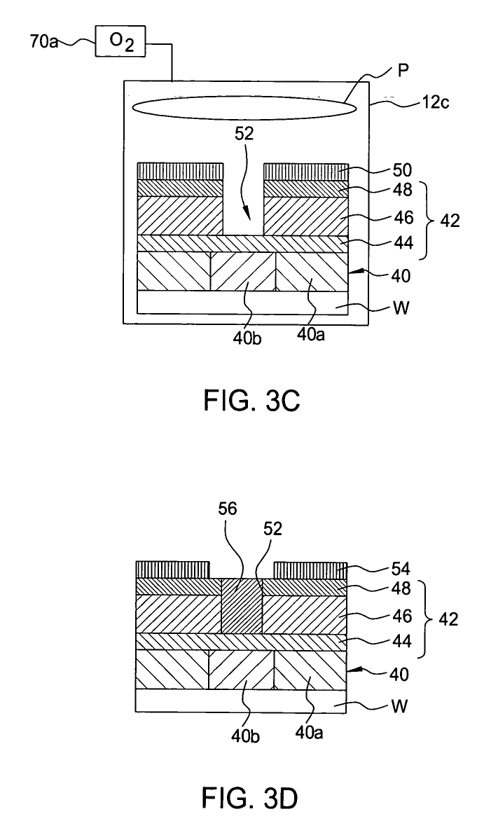

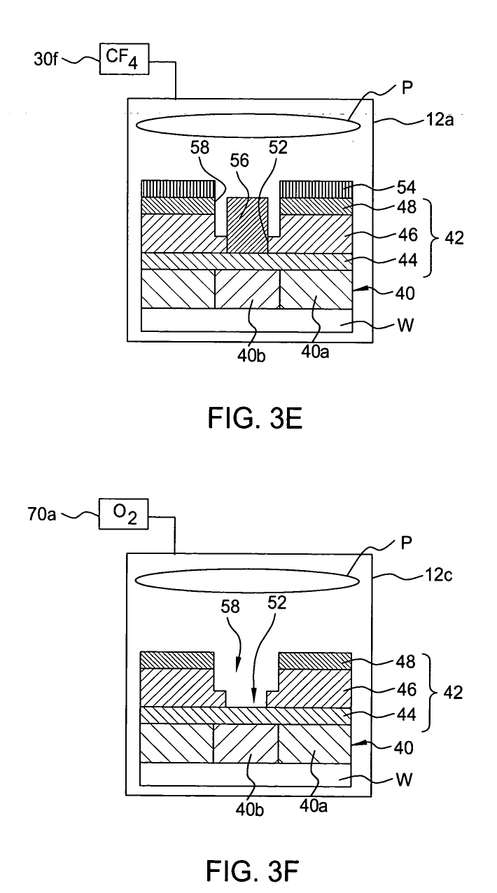

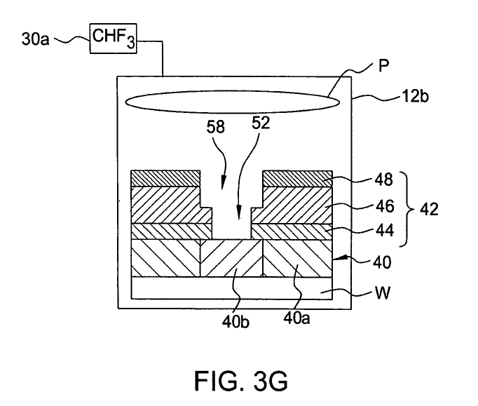

The method according to the embodiment using the substrate processing system 1 is explained below. FIG. 3(a) is a view schematically showing an insulator layer stack 42 on which a first resist mask 50 for forming a via hole is deposited.

The insulator layer stack 42 is formed on a metal wiring layer 40 provided on the wafer W. The metal wiring layer 40 comprises a metal wiring layer 40b surrounded by an insulator layer 40a formed of an oxide. The thickness of the metal wiring layer 40 is generally about 0.4 microns. The metal wiring layer 40b may be formed, for example, of copper (Cu), aluminum (Al), tungsten (W), and the like.

The insulator layer stack 42 includes a barrier layer 44, a first insulator layer 46, and a second insulator layer 48. The barrier layer 44 is formed on the metal wiring 42. The barrier layer 44 is a silicon carbide-containing material such as silicon carbide (SiC), silicon carbon nitride (SiCN), and the like. The thickness of the barrier layer 44 is generally about 0.05 microns. The first insulator layer 46 is formed on the barrier layer 44. The thickness of the first insulator layer 46 is generally about 0.3 microns. The first insulator layer 46 is an insulator layer having a low dielectric constant. The material of the first insulator layer 46 may be, for example, organosilicate (SiOC), fluorosilicate glass (FSG), and the like. The barrier layer 44 is provided in order to suppress a reaction with the copper wiring 40b of the metal wiring layer 40 when the first insulator layer 46 is formed on the substrate. The barrier layer 44 also functions as an etch stop layer when etching the first insulator layer 46.

The second insulator layer 48 is formed on the first insulator layer 46. The thickness of the second insulator layer 48 is generally about 0.2 microns. The second insulator layer 48 may comprise tetraethylorthosilicate (TEOS), spun on glass (SOG), and the like.

In one illustrative embodiment, as shown in FIG. 3(a), a first resist mask 50 having an opening for forming a via hole therein is formed on the second insulator layer 48 of the insulator layer stack 42.

At the next step, a via hole is formed through the second insulator layer 48 and first insulator layer 46 of the insulator layer stack 42. FIG. 3(b) schematically shows a step of forming a via hole 52. This process is executed in the processing chamber 12a shown in FIG. 1. A gas supply system 30 of the processing chamber 12a has a gas supply source 30f. The process gas supplied from the gas supply source 30f includes carbon tetrafluoride (CF₄), and the like. The process gas is supplied from the gas supply source 30f into the reaction chamber 20, and a plasma is formed between the parallel flat electrodes 22 and 24. The first insulator layer 46 and second insulator layer 48 of the insulator portion 42 disposed on the electrode 22 are etched by the active species in the process gas, and a via hole 52 is formed in the insulator portion 42. In addition, in order to obtain the selectivity of the first insulator layer 46 to the barrier layer 44, the process gas used for etching the first insulator layer 46 may be changed from carbon tetrafluoride (CF₄) to a gas mixture comprising fluorobutylene (C₄F₆) and nitrogen (N₂) just before the via hole 52 extends to the barrier layer 44 during etching of the first insulator layer 46.

At the next step, ashing may be performed in-situ in the processing chamber 12a. Alternatively, as depicted in FIG. 3(c), the processing chamber 12c may be a separate ashing apparatus, such as an AXIOM™ hexafluorobutadiene processing chamber, available from Applied Materials, Inc. FIG. 3(c) is a sectional view schematically showing the step of removing the first resist mask 50. In the processing chamber 126, oxygen is supplied into the chamber from an oxygen supply source 70a, and a plasma is formed in the chamber, thereby the first resist mask 50 is removed.

At the next step, a second mask is formed in order to form a trench in the first insulator layer 46 and the second insulator layer 48. FIG. 3(d) is a sectional view of the insulator portion 42 on which a second mask for forming a trench is formed. In one illustrative embodiment, a second resist mask 54 having an opening for forming a trench is formed on the second insulator layer 48. The via hole 52 is filled with a mask 56 made of same material called BARC (bottom anti-reflective coating) as is the second resist mask 54.

At the next step, by etching the insulator portion 42 using the second resist mask 54, a trench 58 is formed. FIG. 3(e) is a view schematically showing the step of forming the trench 58. The trench 58 is formed to a specified depth in the first insulator layer 46. This process is also executed in the processing chamber 12a. The process gas used in this process is the same as that used in formation of the via hole 52.

At the next step, the second resist mask 54 and BARC mask 56 for forming the trench are removed. FIG. 3(f) is a view schematically showing the step of removing the trench forming masks. This process of ashing is also executed in-situ or in the chamber 12c, and the second resist mask 54 and the BARC mask 56 are removed, e.g., using oxygen plasma ashing.

At the next step, a via hole 52 is formed through the barrier layer 44. The via hole 52 is a hole communicating with the under-layer wiring 40b of the metal wiring layer 40. FIG. 3(g) is a sectional view schematically showing the step of forming the via hole 52 through the barrier layer 44. This process is executed in the processing chamber 12b. In the processing chamber 12b, the process gas containing e.g., trifluoromethane (CHF₃) is supplied from the gas supply source 30a into the reaction chamber 20. By using the trifluoromethane (CHF₃), and the like, the barrier layer 44 can be etched selectively.

Thereafter during subsequent steps, the insulator portion 42 is wet-cleaned, and the insulator portion 42 is plated with, e.g., copper (Cu), whereby the via holes 52 and trenches 58 are filled with copper (Cu). The copper (Cu) deposited on the surface of the second insulator layer 48 is removed by chemical mechanical polishing (CMP).

The action and effect of the first embodiment are explained as follows. According to the method of the first embodiment, the process gas for etching the barrier layer 44 includes trifluoromethane (CHF₃). It is noted that trifluoromethane (CHF₃) hardly generates any polymers containing hydrogen atoms and carbon atoms, as compared with conventional process gas, such as, e.g., difluoromethane (CH₂F₂), and therefore there is hardly any deposition of polymers in the reaction chamber 20 of the chamber 12b. Accordingly, the chamber 12b maintains a favorable MWBC.

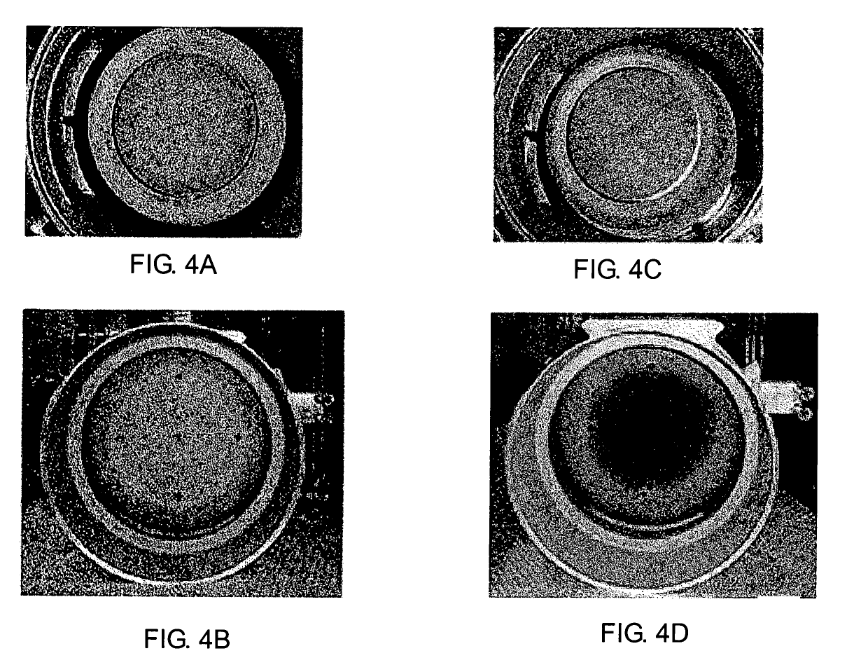

FIG. 4(a) shows the state of a cleaned reaction chamber 20 of the chamber 12b. FIG. 4(b) shows the state of the reaction chamber shown in FIG. 4(a) after 2 hours of etching using trifluoromethane (CHF₃) as a process gas. FIG. 4(c) similarly shows the state of a cleaned reaction chamber 20 of the chamber 12b in the same state as in FIG. 4(a), and FIG. 4(d) shows the state of the reaction chamber shown in FIG. 4(c) after 2 hours of etching using difluoromethane (CH₂F₂) as a process gas.

As shown in FIG. 4(d), when difluoromethane (CH₂F₂) is used as the process gas, after 2 hours of etching, excessive polymers are deposited in the reaction chamber. By contrast, when trifluoromethane (CHF₃) is used as the process gas as shown in FIG. 4(b), after 2 hours of etching, polymers are hardly deposited in the reaction chamber 20, and the same state as the initial clean state shown in FIG. 4(a) is maintained.

A method of forming a damascene structure according to a second embodiment of the invention is described below. A processing chamber 12b of a substrate processing system 1 may also be used in the second embodiment. This processing chamber 12b is adapted to receive the process gas supplied from a gas supply system 30. The gas supply system 30 of the chamber 12b comprises a gas supply source for supplying a process gas containing trifluromethane (CHF₃) and the like and a gas supply source for supplying oxygen (O₂). The process gas containing trifluoromethane (CHF₃) and the process gas containing oxygen (O₂) may be independently supplied into the reaction chamber 20. Therefore, by using the chamber 12b, both oxygen plasma ashing and etching using a process gas including trifluoromethane (CHF₃) can be executed.

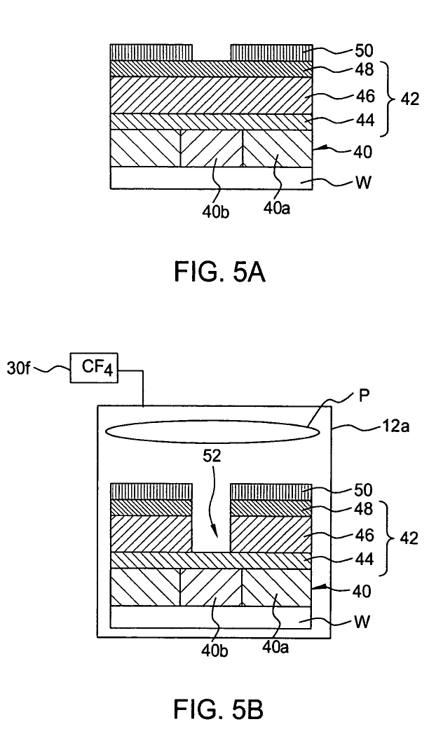

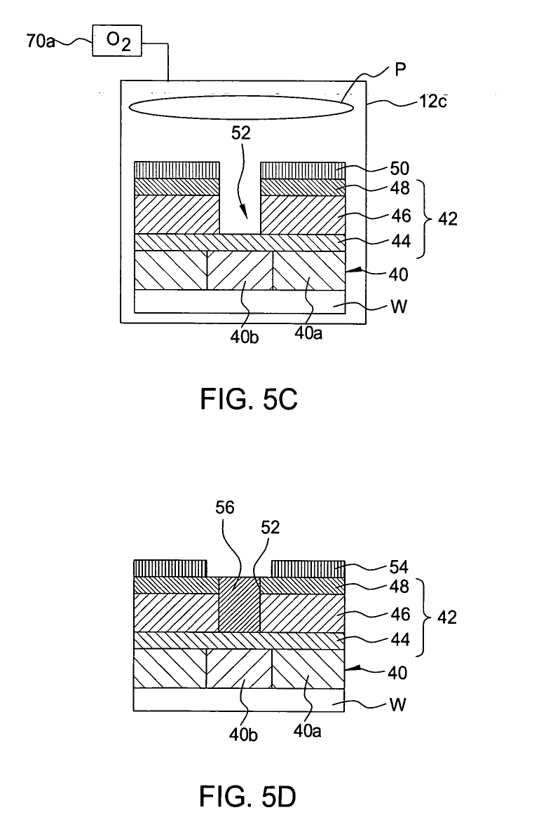

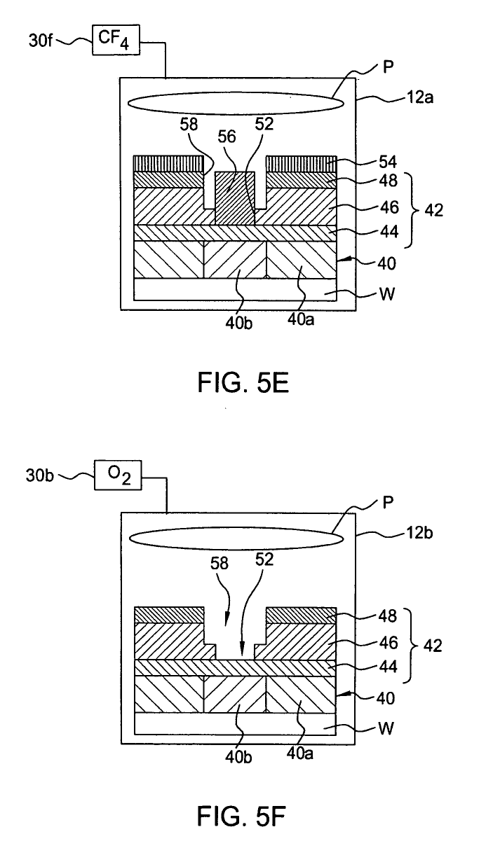

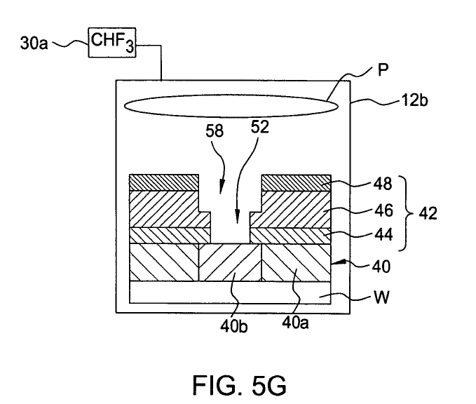

FIGS. 5(a)-5(g) are views schematically showing the process of this embodiment. In this method, the ashing step of second resist mask 54 and mask 56 by oxygen (O₂) plasma ashing shown in FIG. 5(f) and the etching step of via hole 52 in barrier layer 44 by trifluoromethane (CHF₃) shown in FIG. 5(g) are executed in process chamber 12b. Other steps are the same as in the first embodiment discussed above.

The action and effect of the second embodiment are explained as follows. According to this method, the process gas for etching the barrier layer 44 contains trifluoromethane (CHF₃), and polymers are hardly deposited in the reaction chamber 20 of the chamber 12b. Therefore, the MWBC is favorably maintained by the chamber 12b. Further, in the chamber 12b, if polymers are deposited in the reaction chamber 20, they are removed by oxygen plasma ashing.

Besides, since there is hardly any deposition of polymers in the reaction chamber, after forming the via hole 52 in the barrier layer 44, polymers are hardly deposited on the surface of the under-layer wiring 40b of the metal wiring layer 40. Therefore, the resistance value of the multi-layer wiring including the under-layer wiring 40b formed by plating is maintained at a low level by minimizing and/or eliminating parasitic (i.e., resistance raising) polymer deposits.

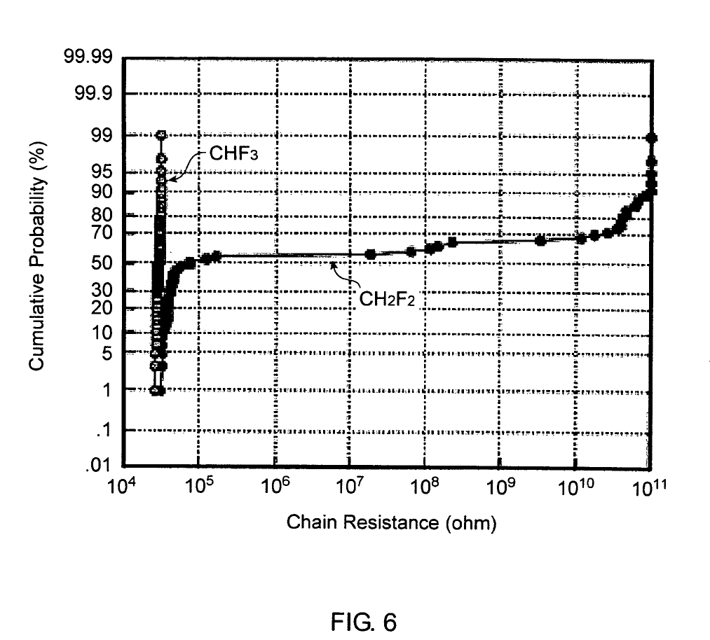

FIG. 6 is a graph showing resistance measurement results for multi-layer wiring manufactured by the method described with reference to FIGS. 5(a)-5(g), having the barrier layer etched by the gas including trifluoromethane (CHF₃) as compared to difluoromethane (CH₂F₂).

In the graph in FIG. 6, the abscissa denotes the chain resistance, and the ordinate represents the cumulative probability. As clear from the graph in FIG. 6, the chain resistance is higher in the multi-layer wiring having the barrier layer etched by difluoromethane (CH₂F₂). On the other hand, in the present method of etching the barrier layer 44 using trifluoromethane (CHF₃), the chain resistance of the multi-layer wiring of the manufactured damascene structure has a low value, and it is evident that fluctuations of chain resistance are small.

According to this method, when the via hole 52 is formed in the barrier 44 using trifluoromethane (CHF₃), it is also effective to suppress roughening of the surface of the second insulator layer 48 and inner wall surface of the trench 52 exposed to the process gas.

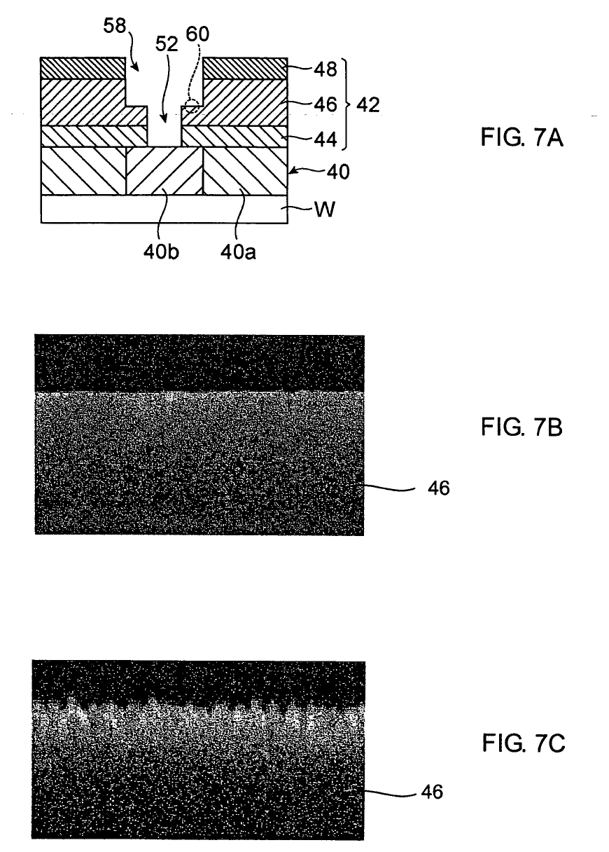

FIG. 7(a) is a sectional view of the insulator portion 42 manufactured by this method. FIG. 7(b) is a scanning electron microscope (SEM) photograph showing a section of the first insulator layer 46 in the bottom of the trench 58 of the insulator portion 42 manufactured by this method. FIG. 7(c) is a SEM photograph showing a section of the first insulator layer in the bottom of the trench of the insulator portion in which the via hole is formed in the barrier layer in the conventional method, i.e., by the proess gas including difluoromethane (CH₂F₂). In the conventional method, when the via hole is formed in the barrier layer, polymers are deposited on the surface of the first insulator layer in the bottom of the trench as a micro mask. As a result of exposure to process gas used in etching of barrier layer in this state having such micro mask, the surface of the first insulator layer in the bottom of the trench is roughened as shown in FIG. 7(c).

On the other hand, according to the inventive method, there is hardly any deposition of polymers, and polymers are rarely deposited on the surface 60 of the first insulator layer 46 in the bottom of the trench 58. Therefore, as shown in FIG. 7(b), if the barrier layer 44 is etched, the surface 60 is kept smooth.

A method of forming a damascene structure according to a third embodiment of the invention is described below. A processing chamber 12b of a substrate processing system 1 may also be used in the method of the third embodiment. This processing chamber 12b has a gas supply system 30 consisting of a gas supply source for supplying trifluoromethane (CHF₃) and the like, a gas supply source for supplying oxygen (O₂), a gas supply source for supplying nitrogen (N₂), and a gas supply source for supplying an inert gas, such as argon (Ar), and the like. The gas supply system 30 can switch the gases to be supplied in the reaction chamber 20.

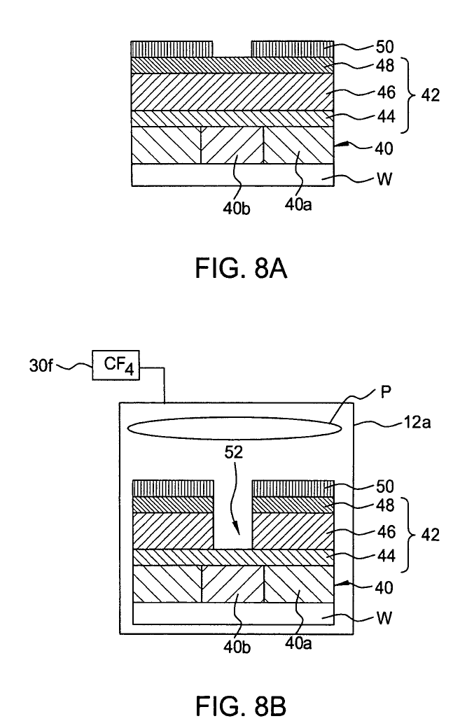

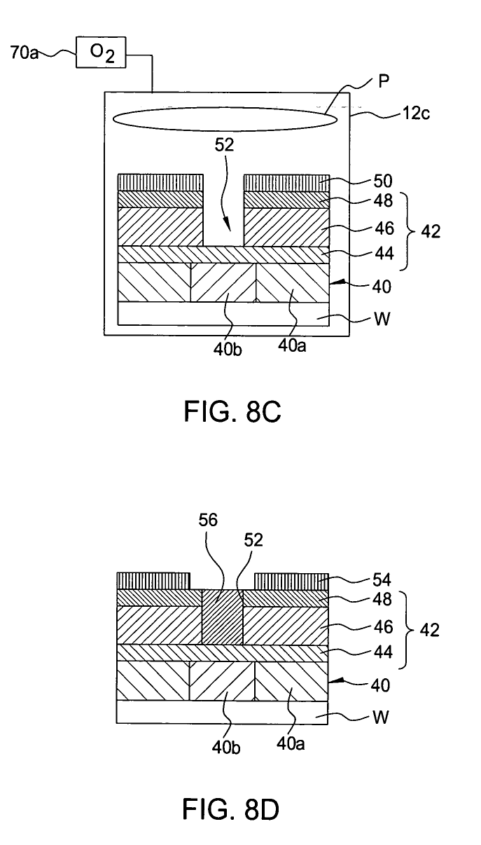

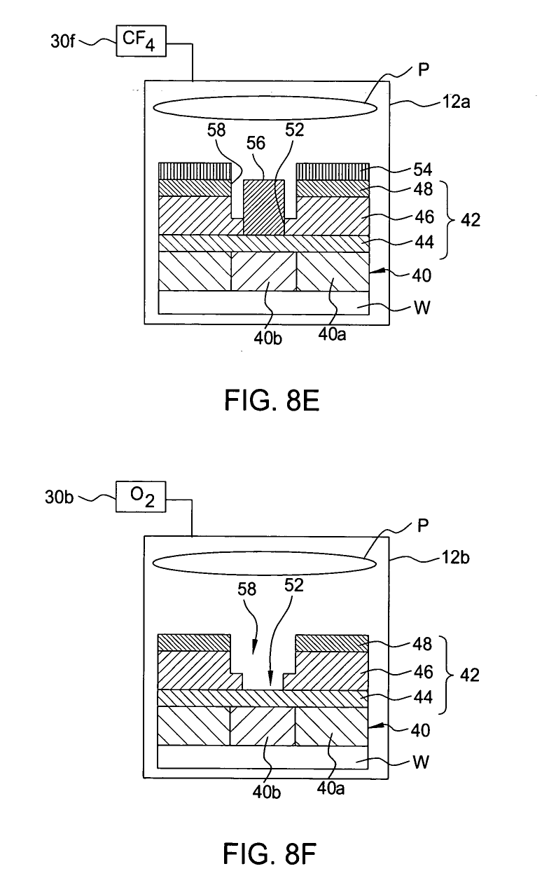

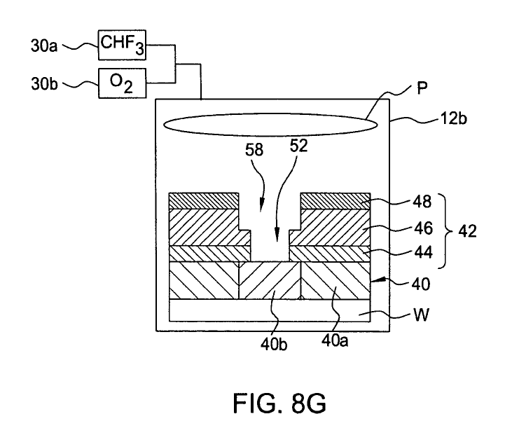

FIGS. 8(a)-8(g) are views schematically showing the process of this embodiment. In the method of this embodiment, what differs from the second embodiment is that the process gas used in etching of the barrier layer 44 includes trifluoromethane (CHF₃) and oxygen (O₂). Other steps of this method are same as in the second embodiment discussed above. Instead of oxygen (O₂), nitrogen (N₂) may also be used. In addition, the process gas may also contain argon (Ar).

The action and effect of the third embodiment are explained. According to this method, the process gas for etching the barrier layer 44 includes oxygen (O₂) or nitrogen (N₂). Using the process gas including trifluoromethane (CHF₃), oxygen (O₂), and nitrogen (N₂), when the barrier layer 44 comprising silicon carbide (SiC) or silicon carbon nitride (SiCN) is exposed to the process gas for a long period of time for etching, the surface of the second insulator layer 48 and the inner wall surface of the trench 52 become roughened.

On the other hand, by using the process gas including trifluoromethane (CHF₃) and either oxygen (O₂) or nitrogen (N₂), as the via hole 52 is formed in the barrier layer 44, the surface of the second insulator layer 48 and the inner wall surface of the trench 52 are kept smooth.

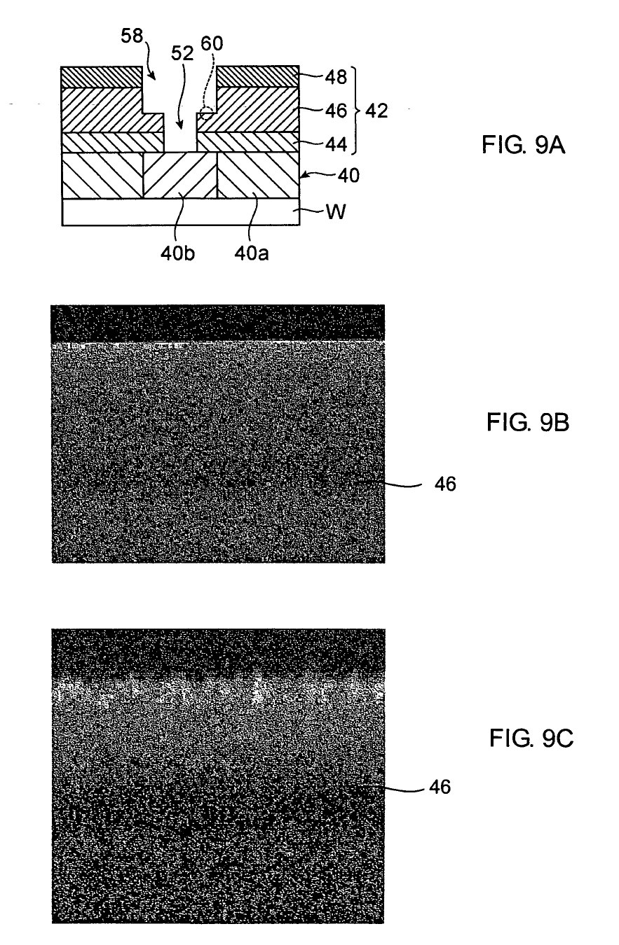

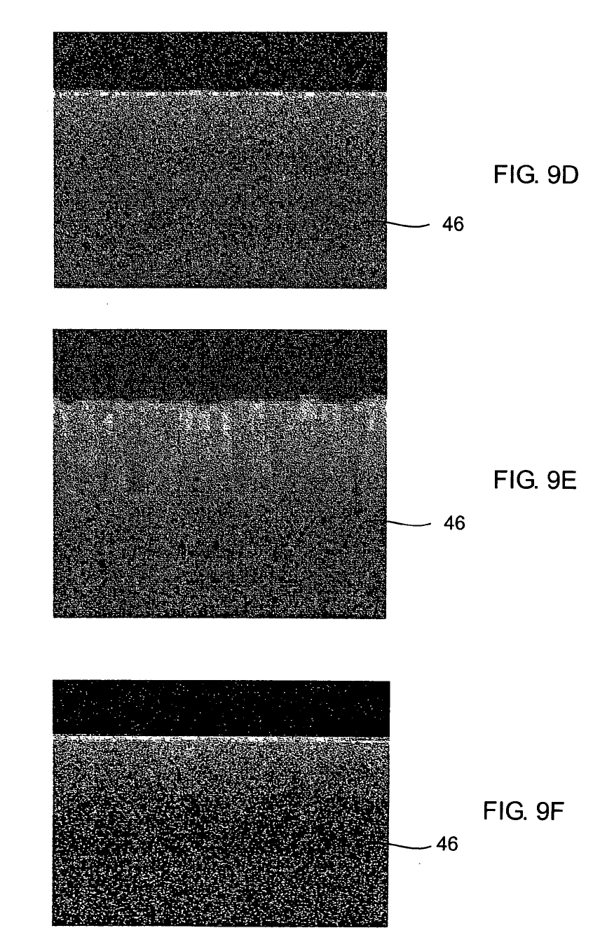

FIG. 9(a) is a sectional view of the insulator portion 42 of the substrate manufactured by the method described with reference to FIGS. 8(a)-8(g). FIG. 9(b) is a SEM photograph showing a section the first insulator layer 46 in the bottom of the trench 58 of the insulator portion 42, showing a state of etching the barrier layer 44 using a process gas mixture including CHF₃:N₂ provided at a flow ratio of 30:50. FIG. 9(c) is a SEM photograph showing a section of the first insulator layer in the bottom of the trench of a similar insulator portion, showing a state of etching of barrier layer using a process gas mixture including CHF₃: O₂:N₂ provided at a flow ratio of 30:5:50. FIG. 9(d) is a SEM photograph showing a section of the first insulator layer 46 in the bottom of the trench 58 of the insulator portion 42, showing a state of etching of barrier layer 44 using a process gas mixture of CHF₃: O₂ provided at a flow ratio of 30:10. FIG. 9(e) is a SEM photograph showing a section of the first insulator layer in the bottom of the trench of a similar insulator portion, showing a state of etching of barrier layer using a process gas mixture of CHF₃: O₂: N₂ provided at a flow ratio of 30:10:50. FIG. 9(f) is a SEM photograph showing a section of the first insulator layer 46 in the bottom of the trench 58 of the insulator portion 42, showing a state of etching of barrier layer 44 using a process gas mixture of CHF₃:O₂:Ar provided at a flow ratio of 30:10:50.

As shown in FIGS. 9(c) and (e), when the barrier layer is etched using the process gas including trifluoromethane (CHF₃), oxygen (O₂) and nitrogen (N₂), the surface of the first insulator layer in the bottom of the trench becomes roughened due to exposure to the process gas for a long time.

On the other hand, when the barrier 44 is etched using the process gas including trifluoromethane (CHF₃) and either nitrogen (N₂) or oxygen (O₂), as shown in FIG. 9(b) and FIG. 9(d), the surface 60 of the first insulator layer 46 in the bottom of the trench 58 is kept smooth. Also, when the barrier layer 44 is etched using the process gas including argon (Ar) along with trifluoromethane (CHF₃) and further including nitrogen (N₂) or oxygen (O₂), the surface 60 is kept smooth as shown in FIG. 9(f).

The methods of the first, second and third embodiments explained above relate to the method of forming a dual damascene structure. The concept of the invention for etching the barrier layer containing silicon carbide (SiC) or silicon carbon nitride (SiCN) by the process gas mainly comprising trifluoromethane (CHF₃) is not limited to the dual damascene structure, but may be also applied in a method of forming a single damascene structure.

As explained herein, the present invention provides a method of forming a damascene structure in an insulator portion having a barrier layer comprising silicon carbide (SiC) or silicon carbon nitride (SiCN), while maintaining a favorable Mean Wafers Between Cleaning (MWBC).

While the foregoing is directed to the illustrative embodiment of the present invention, other and further embodiments of the invention may be devised without departing from the basic scope thereof, and the scope thereof is determined by the claims that follow.

What is claimed is:

1. A method of forming a damascene structure comprising:
(a) providing a substrate having a feature defined through a first dielectric layer formed on a barrier layer comprising one of a silicon carbide (SiC) layer and a silicon carbon nitride (SiCN) layer deposited on a metal wiring layer;
(b) generating a plasma from a gas mixture comprising trifluoromethane (CHF₃); and
(c) etching the barrier layer using the plasma to transfer the feature therethrough to the metal wiring layer.

2. The method of claim 1 wherein the first dielectric layer comprises one of organosilicate (SiOC) and fluorosilicate glass (FSG).

3. The method of claim 1 wherein the gas mixture further comprises one or more gases selected from the group consisting of nitrogen (N₂), oxygen (O₂) and argon (Ar).

4. The method of claim 3 wherein the gas mixture comprises trifluoromethane (CHF₃) and nitrogen (N₂) at a CHF₃:N₂ flow ratio of 30:50.

5. The method of claim 3 wherein the gas mixture comprises trifluoromethane (CHF₃) and oxygen (O₂) at a CHF₃:O₂ flow ratio of 30:10.

6. The method of claim 3 wherein the gas mixture comprises trifluoromethane (CHF₃), oxygen (O₂) and argon (Ar) at a CHF₃:O₂:Ar flow ratio of 30:10:50.

7. A method of forming a damascene structure comprising:
(a) providing a substrate having a feature defined through a first dielectric layer formed on a barrier layer comprising one of a silicon carbide (SiC) layer and a silicon carbon nitride (SiCN) layer deposited on a metal wiring layer;
(b) generating a plasma from a gas mixture comprising trifluoromethane (CHF₃) one or more gases selected from the group consisting of nitrogen (N₂), oxygen (O₂) and argon (Ar); and
(c) etching the barrier layer using the plasma to transfer the feature therethrough to the metal wiring layer.

8. The method of claim 7 wherein the first dielectric layer comprises one of organosilicate (SiOC) and fluorosilicate glass (FSG).

9. The method of claim 7 wherein the gas mixture comprises trifluoromethane (CHF₃) and nitrogen (N₂) at a CHF₃:N₂ flow ratio of 30:50.

10. The method of claim 7 wherein the gas mixture comprises trifluoromethane (CHF₃) and oxygen (O₂) at a CHF₃:O₂ flow ratio of 30:10.

11. The method of claim 7 wherein the gas mixture comprises trifluoromethane (CHF₃), oxygen (O₂) and argon (Ar) at a CHF₃:O₂:Ar flow ratio of 30:10:50.

12. A computer-readable medium containing software that when executed by a computer causes a semiconductor wafer processing system to form a damascene structure comprising the steps of:
(a) providing a substrate having a feature defined through a first dielectric layer formed on a barrier layer comprising one of a silicon carbide (SiC) layer and a silicon carbon nitride (SiCN) layer deposited on a metal wiring layer;
(b) generating a plasma from a gas mixture comprising trifluoromethane (CHF₃); and
(c) etching the barrier layer using the plasma to transfer the feature therethrough to the metal wiring layer.

13. The computer-readable medium of claim 12 wherein the first dielectric layer comprises one of organosilicate (SiOC) and fluorosilicate glass (FSG).

14. The computer-readable medium of claim 12 wherein the gas mixture further comprises one or more gases selected from the group consisting of nitrogen (N₂), oxygen (O₂) and argon (Ar).

15. The computer-readable medium of claim 14 wherein the gas mixture comprises trifluoromethane (CHF₃) and nitrogen (N₂) at a CHF₃:N₂ flow ratio of 30:50.

16. The computer-readable medium of claim 14 wherein the gas mixture comprises trifluoromethane (CHF₃) and oxygen (O₂) at a CHF₃:O₂ flow ratio of 30:10.

17. The computer-readable medium of claim 14 wherein the gas mixture comprises trifluoromethane (CHF₃), oxygen (O₂) and argon (Ar) at a CHF₃:O₂:Ar flow ratio of 30:10:50.
